(19) United States
(12) Patent Application Publication
(10) Pub. No.: US 2026/0307521 A1
(43) Pub. Date: Oct. 8, 2026

(54) BATTERY CHARGING MANAGEMENT SYSTEM AND CHARGING CONTROL METHOD USING SAME

(71) Applicant: Standard Energy Inc., Yuseong-gu, Daejeon (KR)

(72) Inventor: Dongyoung LEE, Daejeon (KR)

(21) Appl. No.: 19/100,760

(22) PCT Filed: Aug. 4, 2023
(86) PCT No.: PCT/KR2023/011469

§ 371 Date: Feb. 3, 2025

(30) Foreign Application Priority Data
Aug. 4, 2022 (KR) 10-2022-0097420
Aug. 26, 2022 (KR) 10-2022-0107295
Nov. 8, 2022 (KR) 10-2022-0147628

(51) Int. Cl. B60L 53/62; B60L 53/53; B60L 55/00

(52) U.S. Cl. CPC B60L 53/62; B60L 53/53; B60L 55/00

(57) ABSTRACT

The present document relates to a battery charging management system and a charging control method using same. The battery charging management system including an energy storage system (ESS) comprises: a first power meter for measuring the amount of power provided from a power grid; at least one second power meter for measuring the amount of power distributed to a charger, the ESS, and a load other than the ESS through at least one distribution board, the power being provided from the power grid; and a controller for controlling the distribution of power of the power grid on the basis of power information of the first power meter and the at least one second power meter, wherein the ESS uses a battery that supports charge and discharge speeds of a predetermined level or higher.

### TECHNICAL FIELD

The following description relates to a battery charging management system and a charging control method using the same, and more particularly, to a configuration utilizing a plurality of power meters in a battery charging management system including an energy storage system (ESS) and a method for efficiently controlling charging of an electrically driven mobility device using the same.

### BACKGROUND

With a recent expansion of use of electric vehicles, electric vehicle (EV) chargers are placed in various spaces. However, use of the electric vehicle charger may increase an electricity usage of a grid and may affect other electricity usage in the corresponding space. In particular, when the electricity usage increases explosively, the use of the electric vehicle charger is limited.

In addition, as a mobility device requiring battery charging, not only the current electric vehicle, but also various electrically driven mobility devices such as an uncrewed artificial vehicle (UAV) and a personal mobility have been proposed.

Accordingly, there is a need for a method for stably charging the various electrically driven mobility devices described above in the space in which the charger is disposed and providing a system for supporting the same.

### SUMMARY

### Technical Problem

To solve the above-described problems, an aspect of the present disclosure is to propose a battery charging management system for stably performing charging by including an ESS that stabilizes power supply of a grid by assisting power use of a charger, and a plurality of power meters considering characteristics of the corresponding ESS.

In addition, another aspect of the present disclosure is to propose a method for efficiently controlling charging of an electrically driven mobility device from a point of view of a user/a system using the above-described battery power charging management system.

Problems to be solved by the present disclosure are not limited to the problems mentioned above, and other problems not mentioned will be clearly understood by those skilled in the art to which the present disclosure pertains from a following description.

### Technical Solutions

An aspect of the present disclosure for solving the above-described problems proposes a battery charging management system including an energy storage system (ESS) including a first power meter that measures an amount of power provided from a power grid, one or more second power meters that respectively measure amounts of power provided from the power grid and distributed to a charger, the ESS, and a load outside the ESS via one or more distribution boards, and a controller that controls the power distribution of the power grid based on power amount information of each of the first power meter and the one or more second power meters, wherein the ESS uses a battery supporting a charging/discharging speed equal to or higher than a predetermined reference.

Another aspect of the present disclosure for solving the above-described problems proposes a method for controlling charging of an electrically driven mobility device including a battery including obtaining first power amount information provided to the battery from a charger, obtaining second power amount information provided to a load other than the battery from the charger, and displaying warning information on the charger or a user device of the electrically driven mobility device when the second power amount information is equal to or greater than a predetermined reference.

### Advantageous Effects

According to the embodiments of the present disclosure as described above, the ESS that stabilizes the power supply of the grid by assisting the power use of the charger and enables high-speed charging and discharging may be utilized, and data of the plurality of power meters may be utilized, thereby performing fast and various control functions.

In addition, in the charging of the electrically driven mobility device, power consumed in the load other than the battery may be used to control the user to avoid abnormal situations/billing.

Effects obtainable in the present disclosure are not limited to the effects mentioned above, and other effects not mentioned may be clearly understood by those skilled in the art to which the present disclosure pertains from the following description.

### BRIEF DESCRIPTION OF THE DRAWINGS

FIG. 1 is a diagram for illustrating a configuration of a battery charging management system including an ESS to which an embodiment of the present disclosure is to be applied.

FIG. 2 is a diagram for illustrating a battery type applied to an ESS and a concept of utilizing a plurality of power meters according to an embodiment of the present disclosure.

FIG. 3 is a diagram for illustrating a structure of a VIB ESS according to an embodiment of the present disclosure.

FIG. 4 is a diagram illustrating a structure of a battery charging management system including an ESS according to an embodiment of the present disclosure.

FIG. 5 is a diagram illustrating a configuration and a control method of a charging management system utilizing a plurality of power meters according to an embodiment of the present disclosure.

FIG. 6 is a diagram for illustrating a concept of identifying a power error in a PCS/power bank according to an embodiment of the present disclosure.

FIGS. 7 and 8 are diagrams for illustrating a concept of performing grid separation according to an embodiment of the present disclosure.

FIG. 9 is a diagram illustrating a configuration in which an energy storage device is disposed in a space and a configuration in which power is supplied to other electrical devices according to an embodiment of the present disclosure.

FIG. 10 is a diagram illustrating a configuration of an ESS according to an embodiment of the present disclosure.

FIG. 11 is a diagram illustrating an ESS configuration according to another embodiment of the present disclosure.

FIG. 12 is a diagram for illustrating a configuration of an electric vehicle charging system according to an embodiment of the present disclosure.

FIG. 13 is a view for illustrating a method for controlling charging of an electric vehicle including a battery according to an embodiment of the present disclosure.

FIG. 14 is a block diagram of a power measurement device disposed inside a charger and an electric vehicle according to an embodiment of the present disclosure.

### BEST MODE

Hereinafter, embodiments of the present disclosure will be described in detail with reference to the accompanying drawings such that those skilled in the art to which the present disclosure pertains may easily implement the same. However, the present disclosure may be implemented in various different forms and may not be limited to the embodiments described herein. In addition, to clearly illustrate the present disclosure in the drawings, parts irrelevant to the description are omitted, and similar reference numerals are denoted to similar parts throughout the present document.

Throughout the present document, when a part “includes” a certain component, it means that other components may be further included, rather than excluding other components, unless otherwise stated.

In general, an ESS refers to a device capable of storing energy in various energy storage means and then supplying the stored power back to a grid when necessary. Among such ESSs, an ESS using a battery as the energy storage means is specifically referred to as a battery energy storage system (BESS), but unless otherwise specified in the following description, it is assumed that the ESS is the BESS.

In general, the ESS is composed of the battery, a battery management system (BMS), a power conversion system (PCS), an energy management system (EMS), and the like. The battery may include one or more cells, the plurality of cells may constitute one module, and a plurality of modules may constitute one rack. The ESS constructed as such may be connected to an electrical grid, an electric network, a power grid, and the like to receive power.

The ESS may be used for charging various electrically driven mobility devices including an electric vehicle. In the following description, for convenience of description, the ‘electrically driven mobility device’ is described as the electric vehicle, but does not need to be limited thereto.

As described above, use of an electric vehicle charger may increase electricity usage of the grid and affect other electricity usage in the corresponding space, so that when the ESS is used to assist the power usage of the electric vehicle charger, the power usage may be more stably supported.

In the following description, the battery may include a battery applied to the ESS and a battery applied to an inside of the electric vehicle, a state of the corresponding battery may be representatively expressed based on a state-of-charge (SoC), and a charging/discharging speed of the battery may be described based on a charge/discharge rate (C-rate).

First, a charge rate of the battery and/or a discharge rate of the battery may be controlled by the charge/discharge rate (C-rate). The charge/discharge rate (C-rate) refers to a measurement of a current used for charging and/or discharging the battery. For example, discharging a specific battery at 1 C-Rate or 1 C means that a battery having a capacity of 10 Ah (i.e., an amount of electricity when 10 A (ampere) current flows for 1 hour) may discharge 10 A (ampere) for 1 hour from a fully charged state.

When a battery charged at a specific C-Rate is measured, a state-of-charge (SoC) thereof may be identified. When charging the electric vehicle using the ESS, various controls for the charging may be performed by identifying an SoC of the battery inside the ESS, an SoC of the battery inside the electric vehicle, and the like.

Based on the above description, embodiments will be described in detail below with reference to the drawings.

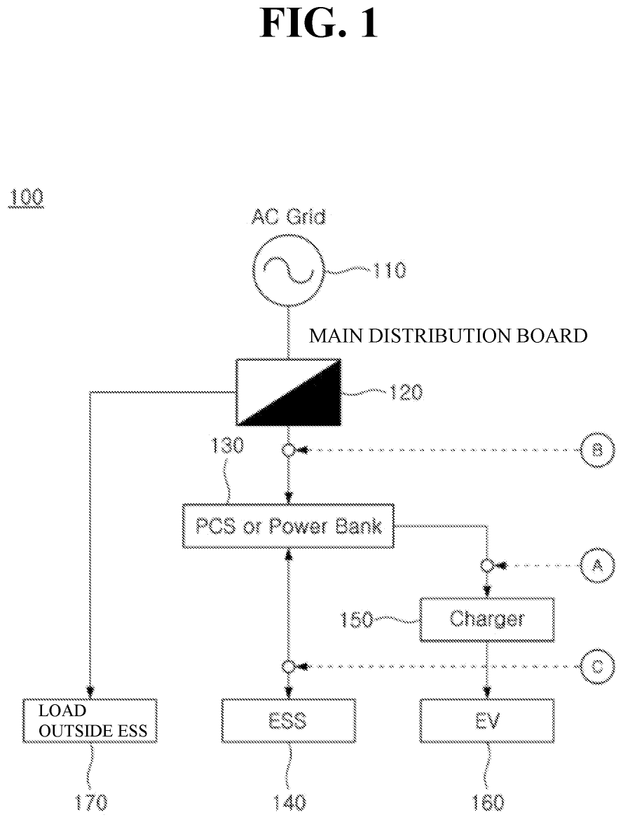

FIG. 1 is a diagram for illustrating a configuration of a battery charging management system including an ESS to which an embodiment of the present disclosure is to be applied.

A battery charging management system 100 to which the present embodiment will be applied may include a power grid 110, an ESS 140, a charger 150 for charging an electric vehicle 160, and a load 170 outside the ESS. In an example of FIG. 1, among various ESSs, a VIB ESS 140 using a vanadium ion battery (VIB) may be used as will be described below, but the present disclosure may not need to be limited thereto. A standard of a battery usable in the ESS 140 according to embodiments of the present disclosure will be described in detail below.

Referring to FIG. 1 in an aspect of power supply, there is a main distribution board 120 that receives power, that is, alternative current (AC), from the power grid 110. The corresponding power may be distributed and provided to a power conversion system (PCS), power bank, or power conversion equipment corresponding thereto 130. In one example, the main distribution board 120 may also be connected to the load 170 outside the ESS to supply the power thereto.

The PCS 130 may be operatively connected to the ESS 140, and may perform a function of converting the AC power into DC power by providing necessary control. In addition, the PCS 130 may be connected to the charger 150, and the charger 150 may be connected to the electric vehicle 160 or another object requiring charging.

The electric vehicle 160 may selectively receive at least one of the power provided from the power grid 110 and the power provided from the ESS 140 under the control of the PCS 130.

In this regard, at least one of the main distribution board 120, the PCS 130, the ESS 140, the charger 150, the electric vehicle 160, and the load 170 outside the ESS may be installed at a specified place, for example, inside or next to a specific building.

It is preferable that such battery charging management system 100 is installed and controlled to supply grid power to the specific building and additionally to perform the electric vehicle charging together. To this end, it is preferable to efficiently control amounts of power in portions indicated by A, B, and C in FIG. 1. To this end, in an aspect of the present disclosure, it is proposed to efficiently control the battery charging using a plurality of power meters.

To efficiently perform control for each load using the plurality of such power meters, it is necessary to first describe a battery type used for the ESS.

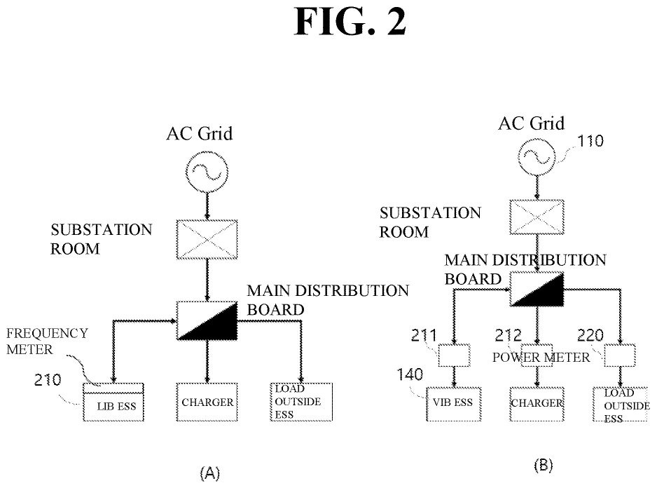

FIG. 2 is a diagram for illustrating a battery type applied to an ESS and a concept of utilizing a plurality of power meters according to an embodiment of the present disclosure.

As described above, there are various types of batteries applicable to the ESS. For example, a lead-acid battery, a lead carbon battery, a sodium sulfur (NAS) battery, a lithium ion battery (LIB), a flow battery, and the like may be used. (A) in FIG. 2 exemplarily illustrates a system to which an LIB ESS 210 to which the LIB, which is currently the most popular among the various batteries for the ESS, is applied.

The LIB is attracting attention because it has high energy density and output density, is about three times lighter than an existing lead storage battery, and is able to reduce a space occupying ratio by 50 to 80% with high power density. In addition, the LIB may discharge 1 to 2% of a charge per month and maintain a long service life, and may be considered to have an advantage of being usable for about 10 years and have 5,000 battery cycles depending on conditions.

However, in the case of LIB, charging and discharging are performed under a basic condition of 0.2 to 0.5 C when operating as the ESS. However, continuous operation thereof is difficult because of heat generation during operation at a high C-rate, and there is a high risk of fire.

In addition, in case of alkaline and lead batteries, they are generally operated at 0.05 C (=20 hours discharge) to avoid a battery capacity degradation (a performance reduction) resulted from the heat generation.

On the other hand, the vanadium ion battery (hereinafter, VIB) developed by the applicant refers to a secondary battery that uses vanadium ions as an active material to electrochemically store/release energy. In an existing vanadium-based battery, an active material (e.g., the vanadium ion, H⁺ cations, water, sulfuric acid, and the like) participating in the electrochemical reaction is forcibly circulated/transferred/stored by a pump or the like operating with an external power and stores/releases electrical energy, whereas in the VIB, the active material in a cell and/or a module performs ion change and movement using an internal electric field, an osmotic pressure, a concentration difference, and the like, and the corresponding active material serves to store/release energy via an electrochemical reaction in the corresponding cell and/or module.

In particular, in the case of vanadium ion battery (VIB), charging and discharging are available at 0.5 to 5 C (MAX 10 C). In addition, because the VIB is operated using a water-soluble electrolyte solution, the VIB is free from the risk of fire and has an advantage of being able to utilize a wide SoC.

Accordingly, (B) in FIG. 2 illustrates a configuration in which the VIB ESS 140 using such VIB is applied according to an embodiment of the present disclosure.

For example, in the case of LIB, heat is generated and the battery life is affected during high power output, but in the case of VIB, stable high power output is available. In addition, in the case of LIB, there is a limitation such as 1 C charging and 1 C discharging, but the VIB is able to perform input/output flow control with a high output, and for example, when a power outage occurs in the grid 110, the VIB ESS 140 is able to assist both the grid 110 and the charger with the high output, so that utilization of the VIB ESS 140 has an advantage of performing very efficient ESS charging/discharging management.

In particular, because there is no risk of fire resulted from overload in the case of VIB, when such VIB is applied to the ESS of the present embodiment, the system of the present disclosure may be preferably applied to various auxiliary facilities while ensuring safety, and thus it may be said that the system is a very effective power supply system. In addition, because safe and efficient energy supply is available when utilizing the VIB ESS 140, the VIB ESS 140 may be used as a very effective, safe, and eco-friendly energy supply means in realizing energy saving, energy environment, carbon neutrality, and the like.

Additionally, when the VIB ESS 140 is used as shown in (B) in FIG. 2, amounts of power measured via a plurality of power meters 211, 212, and 220 may be more efficiently utilized by utilizing a high-speed charging/discharging performance of the VIB as described above. For example, when a measurement value of the power meter 212 that measures an amount of power flowing into the charger is rapidly reduced, it may be supported by high-speed discharging, and when a measurement value of the power meter 220 measured at a load end outside the ESS is equal to or lower than a predetermined reference, the VIB ESS 140 may be charged at a high speed.

In the case of LIB, a relatively narrow voltage range (window) is used because there are an upper limit voltage and a lower limit voltage. Specifically, when the LIB reaches OV or is in a severely discharged state (a state with a voltage lower than the lower limit voltage), a dendritic material is generated and a short circuit resulted from damage to a separator occurs, so that thermal runaway may occur.

On the other hand, in the case of VIB, there is an upper limit voltage, but there is no lower limit voltage, so that a relatively wide voltage range (window) is usable. That is, even in a OV or completely discharged state, no special problem may occur, and thus the VIB may operate more flexibly depending on a measurement situation of the plurality of power meters to be described later.

In addition, in the case of LIB, there is an irreversible reaction (a surface precipitation phenomenon, a solid electrolyte interphase, and a cracking phenomenon) resulted from a phase change when a charging/discharging cycle is repeated, so that a difference in capacity occurs during operation of a predetermined cycle. However, in the case of VIB, there is an advantage that there is no difference in the capacity between an initial capacity and a capacity after operation of the predetermined cycle using a reversible reaction.

Main characteristics of the LIB and the VIB may be summarized as shown in Table 1 below.

TABLE 1

| | LIB | VIB |
|---|---|---|
| Fire risk | High | None |
| Charge/ | 0.2-0.5 C | 0.5-5 C (Max 10 C) |
| discharge rate | | |
| Voltage | Upper limit voltage, lower | Upper limit voltage present, |
| range | limit voltage present | lower limit voltage X |
| Characteristics | Irreversible reaction | Reversible reaction |
| during | because of phase change | |
| cycle | | |
| repetition | | |

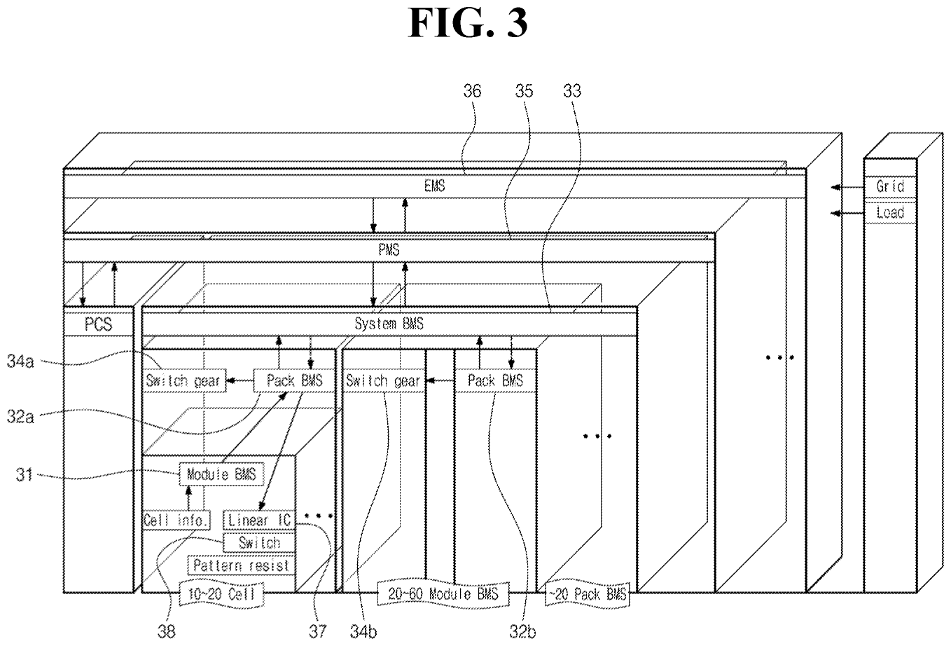

FIG. 3 is a diagram for illustrating a structure of a VIB ESS according to an embodiment of the present disclosure.

As shown in FIG. 3, the VIB ESS also includes the components such as the battery, the BMS, the PCS, and the EMS.

Specifically, the battery may be structured starting from the smallest cell unit, 10 to 20 cells may be grouped together to constitute a module, a plurality of modules may constitute a pack, and a plurality of packs may constitute a system level. In response to such structure, the BMS may also have a hierarchical structure of a cell BMS (not shown), a module BMS 31 (level 1), a pack BMS 32 (level 2), and a system BMS 33 (level 3).

Here, each level means an operation level including other control components as well as the above-described BMS. For example, the level 2 may define a control of the above-described pack BMS 32 with a level 1 control stage and a control operation with respect to a switch gear 34, and the level 3 may define a control operation between the system BMS 33 and a PMS 35. Further, a final level 4 may define a control operation between the plurality of PMSs 35 and an EMS 36.

In this regard, the switch gear 34 may control the battery and a power line (a contactor, a precharge, and a fuse), and a linear IC 37 may receive a command from the pack BMS 32 to turn on a switch 38. In this regard, the switch turn-on may mean balancing by a resistance. Here, the resistance may be a pattern resistance in which a copper line is formed in a pattern on a board.

In the embodiment described with reference to FIGS. 2 and 3, the type of the battery applied to the ESS is exemplarily described as the VIB ((B) in FIG. 2 and FIG. 3), compared to the LIB ((A) in FIG. 2), but the type of the battery applied to the ESS does not need to be limited to the VIB. For example, in the present document, the ESS may utilize a vanadium redox battery (VRB), a polysulfide bromide battery (PSB), a zinc-bromine battery (ZBB), and the like.

In a preferred embodiment of the present disclosure, it is proposed that the ESS uses a battery that supports a charging/discharging speed equal to or higher than a predetermined reference.

As an example, the predetermined reference may be used based on 0.5 C-Rate. Accordingly, a problem in which it is difficult to perform high-speed charging and discharging response in the LIB-based ESS may be solved.

As another example, the predetermined reference may be variably selected and applied based on an installation situation of the ESS within a range of 0.5 C-Rate to 5 C-Rate. For example, the predetermined reference may be variably applied depending on safety or the like of the place where the ESS is disposed. In addition, it is preferable to determine an upper limit of the predetermined reference within a range of 5 C-Rate in consideration of a time during which the ESS is involved in a total time required for charging the electrically driven mobility device such as the electric vehicle.

As another example, the predetermined reference may be utilized based on 0.2 C-Rate, which may be utilized with additional means for dynamically responding to the measurement values of the plurality of power meters while applying the LIB-based battery or the like to the ESS.

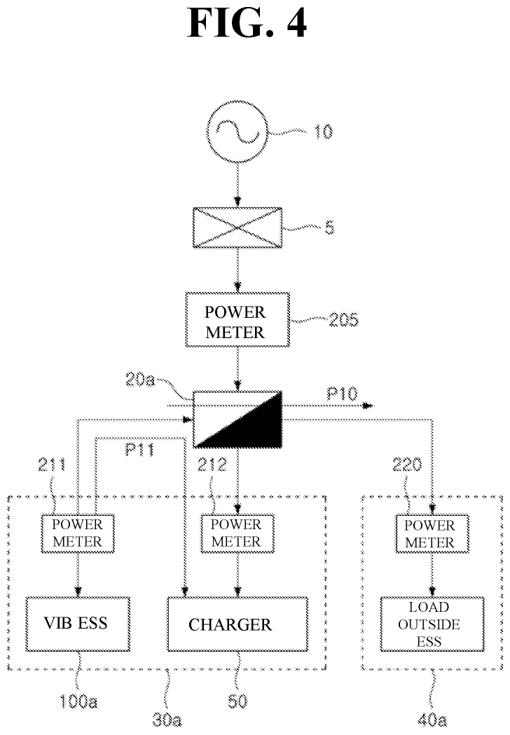

FIG. 4 is a diagram illustrating a structure of a battery charging management system including an ESS according to an embodiment of the present disclosure.

FIG. 4 illustrates a configuration in which a VIB ESS 100a, which is an embodiment of the ESS, is disposed. A process of supplying electricity proceeds in an order of a power source 10, which is a grid, a substation room 5, a first power meter 205, and a power distribution device 20a having the main distribution board as an embodiment. Further, the electricity may be supplied from the power distribution device 20a to the VIB ESS 100a, a charger 50, and a load outside the ESS.

According to the present embodiment, the first power meter 205 that measures an amount of power provided from the power grid, and one or more second power meters 211, 212, and 220 that respectively measure amounts of power distributed to the charger 50, the ESS 100a, and the load 40a outside the ESS via one or more distribution boards are included.

In FIG. 4, an example of placing the power meters (watt-hour meters 211, 212, and 220) for respective lines also in regions 30a and 40a is illustrated. In addition, FIG. 4 illustrates a form in which a support power region 30a and a primary power region 40a are controlled in a partitioned manner. A usage of power branched from the power distribution device 20a may be measured by each of the power meters 211, 212, and 220. Further, a controller disposed in the VIB ESS 100a may receive power consumption information measured by each of the power meters. In this regard, the VIB ESS 100a may include a power management system (PMS), and in this case, the PMS may provide a function of the controller.

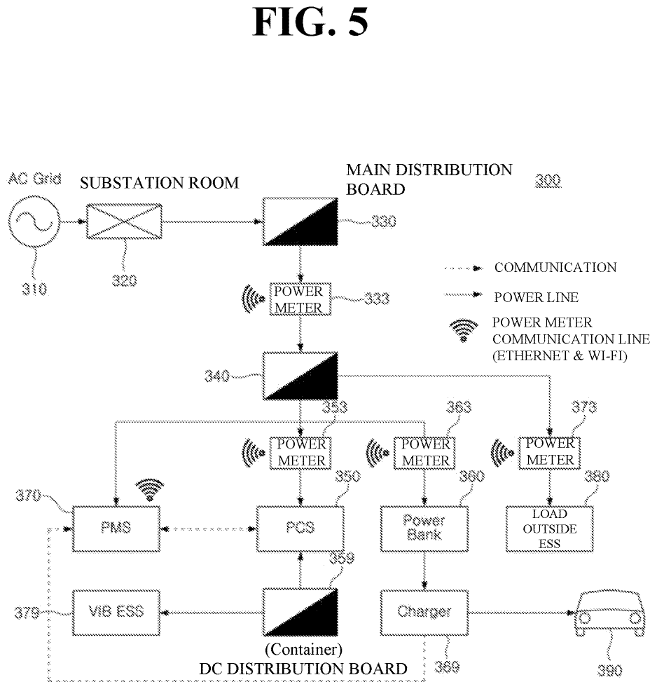

Hereinafter, a control method utilizing the measured power amounts of the first power meter and the one or more second power meters will be described in detail with reference to FIG. 5.

Basically, all or most of components shown in drawings of FIG. 5 and below conceptually represent a specific area, that is, an entire system in which the ESS is installed. In this regard, the system in which the ESS is installed may be a single building, or may mean a specific region or area in which power should be supplied together from the power grid and the ESS in a form of a commercial facility, a factory complex, or the like having several buildings.

An example in which an operating system 300 based on a plurality of power meters according to the present embodiment is applied to an ESS and electric vehicle charger-integrated system will be described as an example, but the operating system 300 is also be applicable to other types of ESS configurations and commercial application examples.

In addition, although power meters are exemplarily shown in the drawings, monitoring means, devices, sensors, measuring instruments, measuring apparatuses, power meters, and the like for identifying and comparing various amounts of power may be used, and equipment and technology of wired communication such as Ethernet or of wireless communication such as Wi-Fi may be used for transmission and reception of the corresponding power amount information.

FIG. 5 is a diagram illustrating a configuration and a control method of a charging management system utilizing a plurality of power meters according to an embodiment of the present disclosure.

The power provided from a power grid (e.g., AC grid) 310 may undergo necessary transformation via a substation room 320, and be delivered to a main distribution board 330. The main distribution board 330 may be connected to at least one lower distribution board. An ESS distribution board 340 is exemplarily illustrated in FIG. 5.

The ESS distribution board 340 may largely transmit power for the ESS/charger and power for a load outside the ESS via distribution. A load 380 outside the ESS may be various and may include electricity/power required for various mechanical equipment such as lighting, a communication network including a server, an air conditioning system, an elevator, and the like of the corresponding building.

The power for the ESS/charger may be provided to a PMS 370 that performs power management, a PCS 350 that performs power conversion and processing, and/or a power bank 360. It is preferable that the PMS 370, the PCS 350, and the power bank 360 are electrically and communicatively connected to each other.

A VIB ESS 379 may be controlled by the PMS 370, and may receive the power from the PCS 350 via a DC distribution board 359. The power bank 360 may transmit the power to a charger 369 to charge an electric vehicle 390. The charger 369 may be controlled by the PMS 370 and may be operatively connected also to the VIB ESS 379.

In FIG. 5, a dotted line is shown to indicate that the PMS 370, the PCS 350, the VIB ESS 379, the charger 369, and the like are able to be communicatively connected to each other. Additionally, the VIB ESS 379 may provide the power by discharging a charged battery to the charger 369, the load 380 outside the ESS, and the like with some power by assisting the power grid depending on a situation, which is indicated by indicating power lines between the VIB ESS 379, the DC distribution board 359, the PCS 350, and the ESS distribution board 340 in both directions.

Hereinafter, an example in which the controller specifically utilizes the power measurement values of the first power meter 333 and the one or more second power meters 353, 363, and 373 will be described based on such configuration.

### First Power Meter 333

In the present embodiment, as described above, it is proposed to utilize the power measurement value of the first power meter 333 that measures the amount of power provided from the power grid 310. Using the power measurement value of the first power meter 333, an amount of power consumed in an entire system compared to an amount of available power of the entire grid may be measured. The controller of the present system may predict a surplus power amount and a deficient power amount using the above measurement, and may obtain and utilize power outage information.

### First Power Meter 333 and Third Power Meter 373

As illustrated in FIG. 5, it is assumed that the second power meter 353, 363, and 373 includes a plurality of power meters for measuring amounts of power branched for respective loads. In this section, to avoid confusion of terms, a power meter that measures an amount of power distributed to the load 380 outside the ESS among the second power meters 353, 363, and 373 will be referred to as a third power meter 373.

By additionally utilizing a power measurement value of the third power meter 373 in addition to the power measurement value of the first power meter 333 described above, the controller according to the present embodiment may additionally measure a power consumption of the load 380 outside the ESS relative to the amount of available power of the entire grid.

By controlling the power consumption of such load outside the ESS, the controller according to the present embodiment may recognize an abnormal power consumption situation of the load outside the ESS, and accordingly, may identify a system error or an ‘electric thief’ that draws and uses the power without permission.

### First Power Meter 333 and Fourth Power Meter 363

In this section, to avoid confusion of terms, a power meter that measures an amount of power distributed to the charger 369 among the second power meters 353, 363, and 373 will be referred to as a fourth power meter 363.

By additionally utilizing a power measurement value of the fourth power meter 363 in addition to the power measurement value of the first power meter 333 described above, the controller according to the present embodiment may additionally measure a power consumption of the electric vehicle charger 369 relative to the amount of available power of the entire grid.

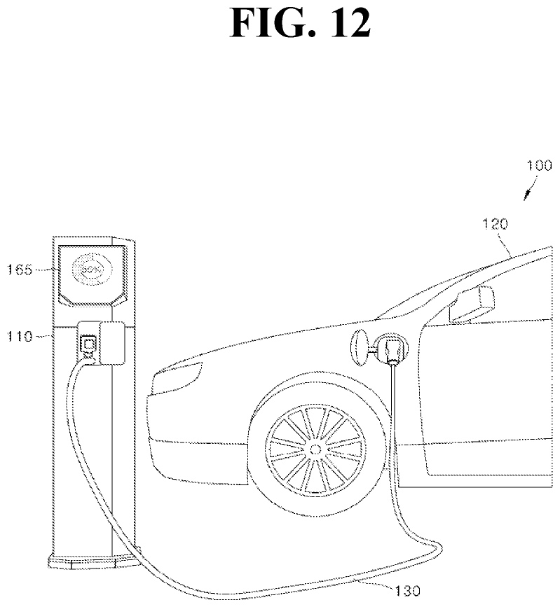

In particular, the measurement of the power consumption of the charger 369 may be used to monitor a billing and a power loss of an object-to-be-charged, such as the electric vehicle, and provide warnings to the user and stop the charging. This will be described in detail below with reference to FIG. 12 and subsequent figures.

### Abnormal Operation Perception

In the case of system using the LIB ESS 210 described above with reference to (A) in FIG. 2, the description has been made focusing on the LIB being difficult to be used for the high-speed charging and discharging and having the risk of fire, but another reason why it is difficult to use the plurality of power meters in the existing system using the LIB ESS 210 is that there is a problem resulted from a noise of the PCS 350. Specifically, there is a high probability that an error occurs in the power measurement value before and after the (high-speed) charging and discharging of the charger 369, and in particular, there is a high probability that an error occurs in the power amount measurement at the PCS 350 stage.

On the other hand, in the present embodiment, the above-described problem is solved using the battery supporting the high-speed charging and discharging at the speed equal to or higher than the predetermined reference (e.g., 0.5 C), like the VIB ESS 379. However, additionally, an actual power consumption and a recognized power consumption of the PCS 350 may be compared with each other via the measurement value of the fourth power meter 363 that measures the amount of power distributed to the charger 369 and a measurement value of a power meter (hereinafter, referred to as a fifth power meter 353 to avoid confusion) for an amount of power distributed to the VIB ESS 379. Further, it is proposed that when a difference therebetween is equal to or greater than a predetermined reference, a failure of the PCS 350 may be determined.

By utilizing such information, the controller according to the present embodiment may manage whether the PCS 350 operates normally, and may manage precision of the PCS 350.

In one example, according to the present embodiment, when measurement of an amount of power of one specific power meter among the first power meter 333 and the one or more second power meters 353, 363, and 373 is not available, the power distribution of the power grid may be controlled and/or the measured amount of power of the specific power meter may be estimated via the measurement of the amounts of power of the remaining power meters except for the specific power meter. For example, in a failure situation of the first power meter 333, the measurement value of the first power meter 333 in which the failure has occurred may be estimated by summing the measurement values of the three second power meters 353, 363, and 373 illustrated in FIG. 5. Further, similarly, when the third power meter 373 fails, the measurement value of the third power meter 373 may be estimated by subtracting the measurement values of the remaining two fourth and fifth power meters 353 and 363 from the measurement value of the first power meter 333.

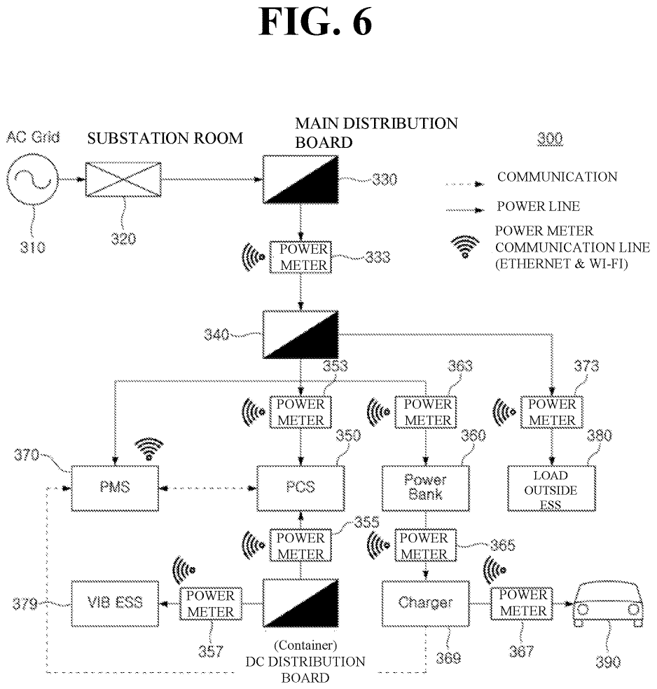

FIG. 6 is a diagram for illustrating a concept of identifying a power error in a PCS/power bank according to an embodiment of the present disclosure.

FIG. 6 illustrates a concept of using an additional power meter for the second power meters 353, 363, and 373 illustrated in FIG. 5. Specifically, in FIG. 6, it is proposed that the second power meters additionally include a sixth power meter 355 that measures an amount of power output from the ESS 350 in addition to the fifth power meter 353 that measures an amount of power distributed to the ESS 379 and input to the PCS 350.

Accordingly, the controller according to the present embodiment may control an error during operation of the PCS 350 by comparing the measured power amount of the fifth power meter 353 with the measured power amount of the sixth power meter 355.

FIG. 6 illustrates an example in which the second power meters additionally include a seventh power meter 365 that measures an amount of power output from the power bank 360 and input to the charger 369, in addition to the fourth power meter 363 that measures an amount of power distributed to the charger 369 and input to the power bank 360.

The controller according to the present embodiment may control an error when charging and discharging of the charger 369 starts by comparing the measured power amount of the fourth power meter 363 described above with the measured power amount of the seventh power meter 365.

In addition, the controller according to an embodiment of the present disclosure may estimate a battery state of the ESS 379 when the battery management system (BMS) of the ESS 379 operates abnormally, based on the measured power amount of the sixth power meter 355. For example, when the SoC of the battery of the ESS 379 is not able to be estimated because of a failure of the BMS, the power introduced into the ESS 379/the SoC of the battery in the ESS 379 may be estimated via the measured power amount of the sixth power meter 355. FIG. 6 illustrates an example in which an additional power meter 357 is included at a stage after power output from the PCS 350 and subsequent to passing through a DC distribution board for more detailed estimation, but the present disclosure does not need to be limited thereto.

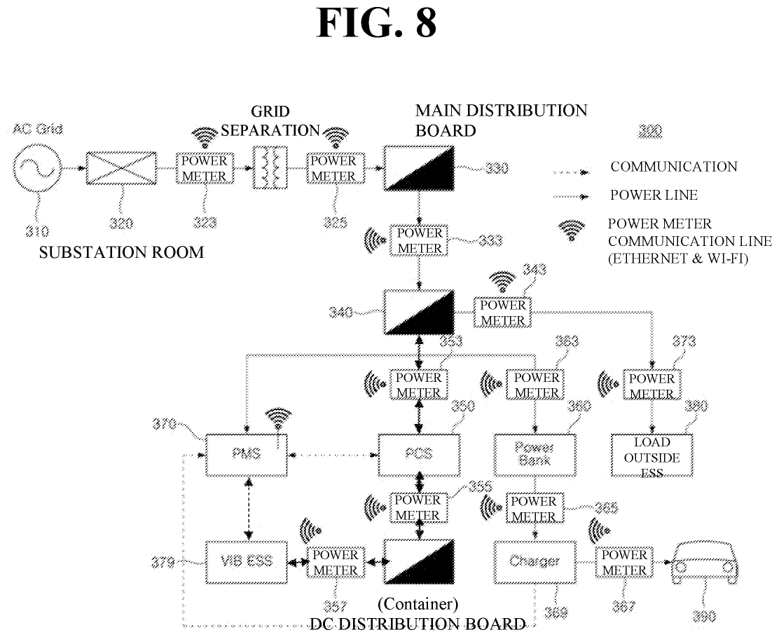

FIGS. 8 and 8 are diagrams for illustrating a concept of performing grid separation according to an embodiment of the present disclosure.

As described above with reference to FIG. 6, the controller may additionally utilize the measured power values of the power meters, such as the sixth power meter 355 and the seventh power meter 365, to determine whether the error at the start of the charging and the discharging of the charger 369 and/or the error at the time of the operation of the PCS 350 is equal to or greater than a predetermined reference.

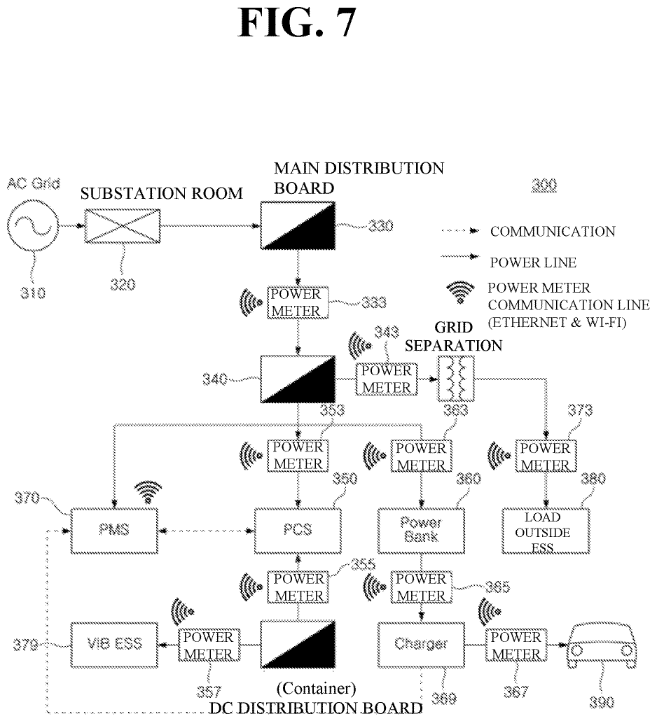

When the controller determines that the error at the start of the charging and the discharging of the charger 369 and/or the error at the time of the operation of the PCS 350 is equal to or greater than the predetermined reference, the controller may control the load 380 outside the ESS to be separated from the power grid as shown in FIG. 7 and/or may control the power grid to be separated from the distribution board 330 as shown in FIG. 8.

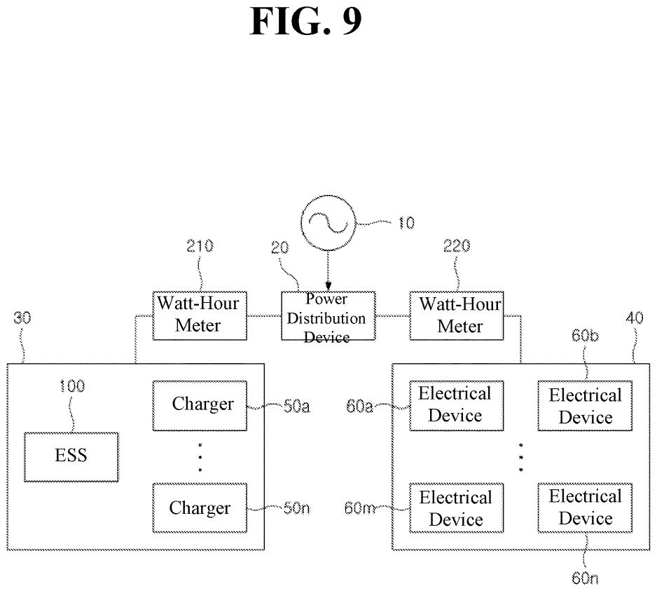

FIG. 9 is a diagram illustrating a configuration in which an energy storage device is disposed in a space and a configuration in which power is supplied to other electrical devices according to an embodiment of the present disclosure.

Specifically, FIG. 9 shows the ESS 100 and other devices that supply power to a supportive power region 30 and a primary power region 40.

In this regard, distinction between the “supportive power region” and the “primary power region” may be sensitive to a problem of causing a problem in power use of an existing user of a site when the charger and the ESS are additionally installed at the specific site for a purpose of charging the electric vehicle or the like. Therefore, a power use region of the existing user is defined as the primary power use region, and power use of the supportive power region is defined as a concept that minimizes influence on the primary power use region. The grid corresponding to a power source 10 may supply the power to the supportive power region 30 and the primary power region 40. The ESS 100 may be disposed in the supportive power region 30.

The power source 10 supplies the power to the corresponding space, and includes an AC grid as an embodiment. The power supplied by the power source 10 is distributed from a predetermined power distribution device 20 to the two or more power regions 30 and 40.

In an embodiment, the power distribution device 20 may supply the power to the supportive power region 30 and the primary power region 40. The power distribution device 20 includes a distribution board as an embodiment.

The primary power region 40 includes a region excluding the supportive power region 30 among regions to which the power is supplied from the power source 10. The ESS 100 according to an embodiment of the present disclosure may supply the power to the supportive power region 30 and the primary power region 40, and may also be disposed in the supportive power region 30.

The ESS 100 and one or more chargers 50a, . . . , 50n may be disposed in the supportive power region 30. Multiple electrical devices 60a, . . . , 60n may be disposed in the primary power region 40. In addition, a separate ESS distinguished from the ESS 100 disposed in the supportive power region 30 may be disposed in the primary power region 40. That is, the separate ESS distinguished from the ESS 100 may also be disposed as an electrical device (e.g., 60 m) in the primary power region 40.

In the embodiment of FIG. 9, the power distribution device 20 may distribute the power to the supportive power region 30 and the primary power region 40. A configuration without the power distribution device 20 may also be included in an embodiment of the present disclosure, and in this case, the power supplied from the power source 10 may be provided to the supportive power region 30 and the primary power region 40 by one power line. In addition, the ESS 100 and the chargers 50a, . . . , 50n receiving a portion or an entirety of the power from the corresponding ESS 100 may be disposed in the supportive power region 30.

The energy storage device (ESS) 100 according to an embodiment of the present disclosure may supply the power to the supportive power region 30 and the primary power region 40 within a maximum range of power supply of the power source 10. The energy storage device 100 may perform charging or discharging based on an electricity demand or an expected demand of the two regions 30 and 40.

To this end, a power meter 210 may be installed by being connected to the supportive power region 30. Alternatively, the power meter 210 may be disposed in the supportive power region 30.

In addition, a power meter 220 may be disposed by being connected to the primary power region 40. Alternatively, the power meter 220 may be disposed in the primary power region 40.

The power meters 210 and 220 include power meters as an embodiment, and measure amounts of power being used in the respective regions where they are installed. The power meters 210 and 220 may transmit the measurement values (the power amounts) to the ESS 100.

In addition, according to an embodiment of the present disclosure, a separate power meter may also be disposed in the power source 10. In this case, the energy storage device 100 may identify a magnitude of power consumed by the power source 10 in real time.

According to another embodiment of the present disclosure, the energy storage device 100 may calculate a total amount of power consumed by the power source 10 by summing power consumption of the power meter 210 in the supportive power region 30 branched from the power distribution device 20 and power consumption of the power meter 220 in the primary power region 40. This may vary depending on an implementation scheme, and the present disclosure may not be limited thereto.

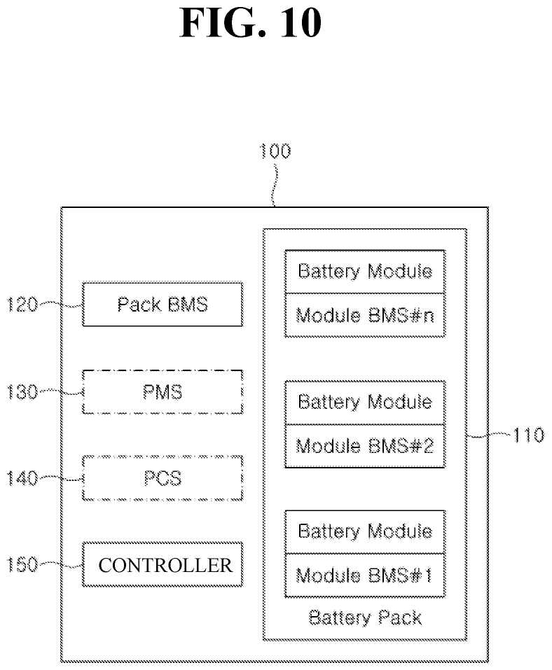

FIG. 10 is a diagram illustrating a configuration of an ESS according to an embodiment of the present disclosure.

The ESS 100 may include an energy storage module 110 including a battery and a controller 150.

The controller 150 may determine charging or discharging of the energy storage module 110 using the power amount measurement result of the supportive power region and the power amount measurement result of the primary power region. In addition, the controller 150 may determine whether to discharge to one or more of the primary power region and the one or more chargers disposed in the supportive power region.

The ESS 100 may include a pack BMS 120 that manages the charging and the discharging of the energy storage module 110. In addition, the ESS 100 may optionally include a PMS 130 and a PCS 140. When the ESS 100 includes both the PMS 130 and the PCS 140, it may be referred to as an integrated ESS.

Alternatively, based on a configuration of the ESS 100, the PMS 130 and the PCS 140 may be physically separated from the ESS 100 and equipped as separate devices. The PMS 130 and the PCS 140 may be independently operated as the separate devices, and may control an operation of the ESS 100 by exchanging information via communication with the ESS 100.

As illustrated, the energy storage module 110 of the ESS 100 may be composed of one or more battery modules and module BMSs that respectively manage the corresponding battery modules. An embodiment of the energy storage module 110 may include a battery pack composed of one or more sets of the battery module—the module BMS.

The battery of the energy storage module 110 may be charged with electricity via the PCS 140. The PCS 140 may receive the electricity and store the same in the battery or may discharge the electricity to a system. In this process, the PCS 140 may perform AC/DC conversion or convert a voltage, a frequency, or the like input/output.

The PMS 130 may exchange information with the PCS 140 via communication, and may provide information necessary for charging, discharging, or controlling the battery to the PCS 140.

The module BMS monitors a charged state, a discharged state, a temperature, a voltage, a current, and the like of the corresponding battery and manages the battery. The pack BMS 120 is a battery management system for the entire battery pack.

The controller 150 may determine the charging or the discharging of the energy storage module 110 using the power measurement result of the supportive power region and the power measurement result of the primary power region, or may determine whether to discharge to the one or more chargers disposed in the supportive power region or to the primary power region. In addition, according to an embodiment, the controller 150 may be integrated with the PMS 130 to operate as one component.

According to an embodiment of the present disclosure, the controller 150 may be an independent component. According to another embodiment of the present disclosure, the controller 150 may be implemented in the PMS 130, and the PMS 130 may provide the function of the controller to be described in the present document.

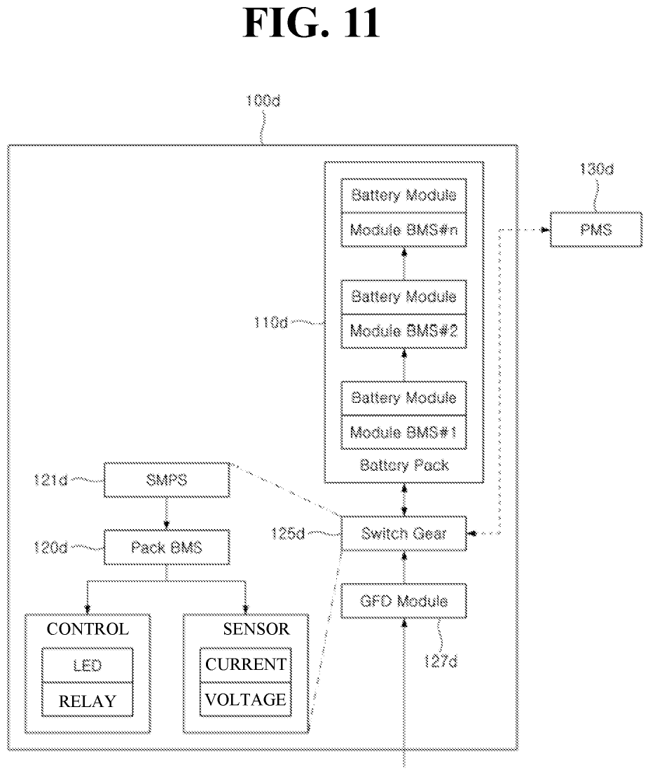

FIG. 11 is a diagram illustrating an ESS configuration according to another embodiment of the present disclosure.

Power supplied from the outside is applied to a battery pack 110d via a ground fault device (GFD) 127d and a switch gear 125d. As a detailed configuration of the switch gear 125d, a switched-mode power supply (SMPS) 121d and a pack BMS 120d are illustrated as an embodiment.

The pack BMS 120d may perform control 128d and sensing 129d, may control an LED and a relay, and may sense a current and a voltage.

In FIG. 11, the switch gear 125d and a PMS 130d may constitute the controller 150 in the above-described embodiments.

When the above-described embodiment is applied, a power supply network includes two or more power sources including the power grid and at least one energy storage system (energy storage device).

The ESS 100 receives a power charging request from a power charger used to charge an object including a rechargeable battery.

The ESS 100 compares a maximum amount of power (Grid_Max) available from the power grid with a sum of a charger power demand (charger charging request) and an amount of power (Primary_Usage) defined for main use.

In addition, when the maximum amount of power (Grid_Max) available from the power grid is equal to or smaller than the sum value, the ESS 100 may perform an operation for power assistance (a first procedure), and otherwise, may perform an operation for charging (a second procedure).

In addition, the ESS 100 may selectively perform the first procedure or the second procedure, so that the power may be provided to the power charger from the power grid alone, from the ESS 100 alone, or from the power grid and the ESS together.

In this regard, the amount of power (Primary_Usage) defined for the main use is related to the power used in the primary power region 40 of the power grid. That is, the load of the building or the like is included.

In the first procedure, as an embodiment, the energy storage system 100 determines an amount of discharge power thereof and performs discharging to support an excess power portion beyond the maximum amount of power (Grid_Max) available from the power grid.

In the second procedure, as an embodiment, when a spare power amount of the power grid is equal to or greater than a reference value, the ESS 100 determines an amount of charge power thereof and performs charging such that the spare power of the power grid is used for the charging, and when the spare power amount of the power grid is equal to or smaller than the reference value, the ESS 100 enters a discharge standby mode.

The controller of the above-described battery charging management system may not only efficiently perform power flow control of the grid using the plurality of power meters, but also efficiently control charging between the charger and the electric vehicle. Hereinafter, the control of the charging between the charger and the electric vehicle will be described in detail.

FIG. 12 is a diagram for illustrating a configuration of an electric vehicle charging system according to an embodiment of the present disclosure.

An electric vehicle charging system 100 illustrated in FIG. 12 may include an electric vehicle 120 that receives power by wire (or wirelessly) and a charger 110 that controls transmission of the power to the electric vehicle 120. The charger 110 may display each of an amount of power actually charged in a battery of the electric vehicle 120 and an amount of power consumed based on the charging via a display 165.

The charger 110 may be connected to the electric vehicle 120 via a power line 130. Alternatively, the charger 110 may be wirelessly connected to the electric vehicle 120.

Further, the charger 110 may include at least one connector storage box, and each connector storage box may include a connector (e.g., a power line RS485) that supplies the power to the electric vehicle 120. The power line 130 may include a power line (e.g., the RS485) that may transmit and receive signals and the power between the charger 110 and the electric vehicle 120.

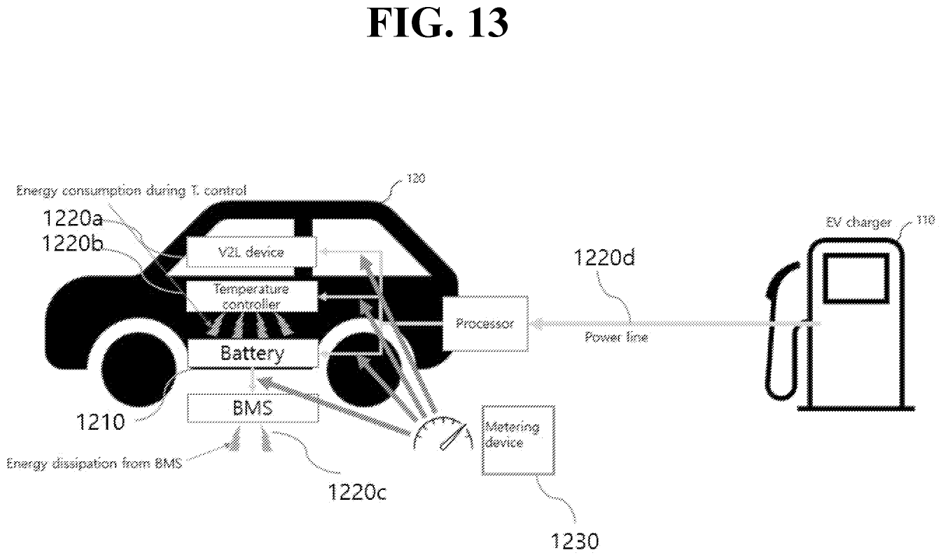

FIG. 13 is a view for illustrating a method for controlling charging of an electric vehicle including a battery according to an embodiment of the present disclosure.

In the present embodiment, it is proposed to acquire first power amount information provided to a battery 1210 of an electric vehicle 120 from a charger 110, also acquire second power amount information provided to a load 1220 other than the battery 1210 from the charger 110, and display warning information on the charger 110 or a user device (e.g., a mobile phone) of the electric vehicle 120 when such second power amount information is equal to or greater than a predetermined reference. That is, when billing for the charging is made based on an amount of power provided from the charger 110, unnecessary billing may be made from a point of view of a user of the electric vehicle 120 when power provided to the load 1220 other than the battery is equal to or greater than a predetermined reference as described above. In a preferred embodiment of the present disclosure, in addition to providing the warning described above, it is proposed to proceed with the billing for the user in consideration of both the above-described first power amount information and second power amount information.

The second power amount information 1220 on the power amount consumed by the load other than the battery may include auxiliary power 1220a used in vehicle to load (V2L) equipment, power 1220b consumed for conditioning of the battery (e.g., an air conditioner for temperature adjustment or the like), power 1220c consumed by a BMS managing the battery, and the like. Such second power amount information 1220 may be measured by a power meter 1230 of the electric vehicle as shown in FIG. 13.

In addition, the above-described second power amount information 1220 may additionally include loss power 1220d between the charger 110 and the electric vehicle 120. Such loss power 1220d may be calculated by comparing a measurement value by the power meter 1230 of the electric vehicle 120 with a measurement value at an output terminal of the charger 110.

In one example, in an embodiment of the present disclosure, determining whether the second power amount information is equal to or greater than the predetermined reference may be performed based on whether the second power amount 1220 exceeds an average of previous measurement values with respect to the power amount provided to the load other than the battery. That is, it is preferable that, when an amount of power equal to or greater than an average amount is provided to the load other than the battery unlike usual, a warning message is controlled to be displayed to the user.

In addition, in another embodiment of the present disclosure, the determination of whether the second power amount information is equal to or greater than the predetermined reference may be made by dynamically calculating a difference between information on a power amount provided to an electrically driven mobility device from the charger and information on a power amount provided to the battery and determining whether the difference is equal to or greater than the predetermined reference.

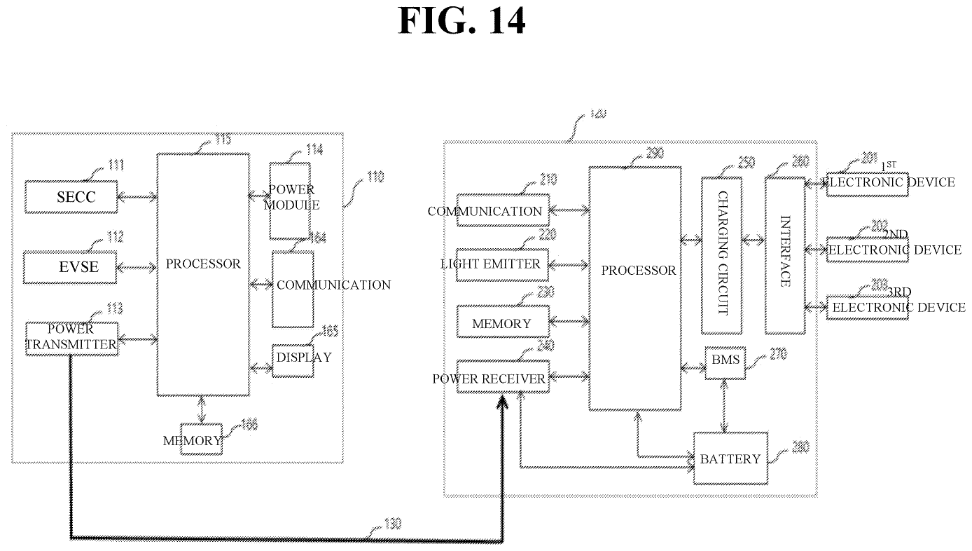

FIG. 14 is a block diagram of a power measurement device disposed inside a charger and an electric vehicle according to an embodiment of the present disclosure.

The charger 110 according to the present embodiment may include an electric vehicle supply equipment (EVSE) 112 and a power module 114. The power module 114 may be equipped on a DC charger, and may not be mounted on an AC charger. In addition, the charger 110 may be equipped with a supply equipment communication controller (SECC) 111 that is a device for controlling a charging procedure by establishing communication with a communication unit (e.g., an EVCC) 210 of the electric vehicle 120.

The power module 114 may include a rectifier, and the rectifier may perform a function of converting external power supplied to the charger 110 into a voltage to be supplied to the electric vehicle 120. For example, the EVCC may correspond to a communication controller that controls communication between a control device inside the electric vehicle and a charging infrastructure for rapid and slow charging of the electric vehicle.

Such EVCC may transmit and receive signals related to control of a state of charge, such as voltage and current, or billing information to and from the charger 110.

The SECC 111 may be in wired/wireless communication with a charging management server, and may transmit/receive electric vehicle information and charging information to/from the communication unit (e.g., EVCC) 210 equipped in the electric vehicle 120. A communication unit 164 of the charger 110 may provide an amount of power charged in the electric vehicle 120, an electric vehicle identification symbol, and a charger identification symbol to the charging management server.

The charger 110 may receive information on the charging of the electric vehicle 120 (e.g., a battery charging voltage, a voltage consumed by each device in the electric vehicle, state information of the battery 280, and the like) from the electric vehicle 120. In addition, the charger 110 may transmit such information on the charging to the charging management server. The charging management server may be communicatively connected to the charger 110 to exchange the information related to the charging of the electric vehicle 120.

The power measurement device in FIG. 14 may provide characteristic information of the electric vehicle. In one example, the charger 110 may receive information related to the power from the electric vehicle. In addition, in the process in which the charger 110 supplies the power to the electric vehicle, the charger 110 may receive a result of charging the battery from the electric vehicle, and accordingly, may identify characteristics of the charging of the electric vehicle. In addition, in this process, the charger 110 may identify an amount of leaked power or an amount of power used regardless of the battery charging.

The detailed description of the preferred embodiments of the present disclosure disclosed as described above has been provided for those skilled in the art to implement and realize the present disclosure. Although the description has been made with reference to the preferred embodiments of the present disclosure, those skilled in the art will understand that the present disclosure may be variously modified and changed without departing from the scope of the present disclosure. For example, those skilled in the art may use each of the components described in the above-described embodiments in a manner of combining them with each other.

Accordingly, the present disclosure is not intended to be limited to the embodiments described herein, but to give a maximum range consistent with the principles and novel features disclosed herein.

### INDUSTRIAL AVAILABILITY

The battery charging management system and the charging control method using the same according to the embodiments of the present disclosure as described above may be utilized not only for charging the electric vehicle but also for charging the various electrically driven mobility devices.

1. A battery charging management system including an energy storage system (ESS), the battery charging management system comprising:
a first power meter configured to measure an amount of power provided from a power source;
one or more second power meters configured to respectively measure amounts of power provided from the power source and distributed to a charger, the ESS, and a load outside the ESS via one or more distribution boards; and
a controller configured to control the power distribution of the power source based on power amount information that is available from the first power meter and the one or more second power meters,
wherein the ESS uses a battery supporting a charging/discharging speed equal to or higher than a predetermined reference.

2. The battery charging management system of claim 1, wherein the predetermined reference is selected in a range of 0.5 C-Rate to 5 C-Rate.

3. The battery charging management system of claim 1, wherein the ESS is a vanadium ion battery (VIB)-based ESS.

4. The battery charging management system of claim 1, wherein the second power meters include a third power meter configured to measure the amount of power distributed to the load outside the ESS,
wherein the controller is configured to control a load consumption by comparing the measured amount of power of the first power meter with the measured amount of power of the third power meter.

5. The battery charging management system of claim 1, wherein the second power meters include a fourth power meter configured to measure the amount of power distributed to the charger,
wherein the controller is configured to control a power consumption of the charger by comparing the measured amount of power of the first power meter with the measured amount of power of the fourth power meter.

6. The battery charging management system of claim 1, wherein the controller is configured to, when a power measurement is not available from any specific power meter among the first power meter and the one or more second power meters, perform one or more of controlling the power distribution of the power source and estimating a measured amount of power of the specific power meter via the amount of power measurement of the remaining power meters except for the specific power meter.

7. The battery charging management system of claim 1, wherein the second power meters include:
a fifth power meter configured to measure power input to a power conversion system (PCS) for distribution to the ESS; and
a sixth power meter configured to measure power output from the PCS,
wherein the controller is configured to determine an error during operation of the PCS by comparing the measured amount of power of the fifth power meter with the measured amount of power of the sixth power meter.

8. The battery charging management system of claim 1, wherein the second power meters include:
a fourth power meter configured to measure an amount of power input to a power bank for distribution to the charger; and
a seventh power meter configured to measure an amount of power output from the power bank and input to the charger,
wherein the controller is configured to determine an error when charging and discharging of the charger starts by comparing the measured amount of power of the fourth power meter with the measured amount of power of the seventh power meter.

9. The battery charging management system of claim 7, wherein when the error at the start of the charging and discharging of the charger or the error at the operation of the PCS is equal to or greater than a predetermined reference, the controller is configured to perform one or more of separating the load outside the ESS from the power source and separating the power source from the distribution boards.

10. The battery charging management system of claim 7, wherein the controller is configured to estimate a battery state of the ESS when a battery management system (BMS) of the ESS operates abnormally, based on the measured amount of power of the sixth power meter.

11. The battery charging management system of claim 1, wherein the controller is configured to manage an abnormal power leak via a comparison between the measured amount of power of the first power meter and the measured amounts of power of the one or more second power meters.

12. The battery charging management system of claim 1, wherein the controller is configured to:
obtain, from the charger, first power amount information provided to a battery of an electrically driven mobility device;
obtain, from the charger, second power amount information provided to a load other than the battery of the electrically driven mobility device; and
control to display warning information on the charger or a user device of the electrically driven mobility device when the second power amount information is equal to or greater than a predetermined reference.

13. A method for controlling charging of an electrically driven mobility device including a battery, the method comprising:
obtaining first power amount information provided to the battery from a charger;
obtaining second power amount information provided to a load other than the battery from the charger; and
displaying warning information on the charger or a user device of the electrically driven mobility device when the second power amount information meets a threshold criterion.

14. The method of claim 13, wherein the second power amount information corresponds to power amount information of power including one or more of:
power consumed for conditioning the battery;
loss power between the charger and the electrically driven mobility device; and
auxiliary power used for vehicle to load (V2L) equipment.

15. The method of claim 13, wherein determining of whether the second power amount information meets the threshold criterion includes determining whether the second power amount exceeds an average of amounts of power provided to the load other than the battery.

16. The method of claim 13, wherein determining of whether the second power amount information meets the threshold criterion includes determining, from the charger, whether a difference between third power amount information provided to the electrically driven mobility device and the first power amount information is equal to or greater than a second predetermined reference.

17. The method of claim 13, wherein the second power amount information is obtained by a power meter configured to measure one or more of:
power consumed for conditioning the battery;
loss power between the charger and the electrically driven mobility device; and
auxiliary power used for vehicle to load (V2L) equipment.

18. The battery charging management system of claim 8, wherein when the error at the start of the charging and discharging of the charger or the error at the operation of the PCS is equal to or greater than a predetermined reference, the controller is configured to perform one or more of separating the load outside the ESS from the power source and separating the power source from the distribution boards.
